(19) United States
(12) Patent Application Publication
(10) Pub. No.: US 2010/0167454 A1
(43) Pub. Date: Jul. 1, 2010

(54) DOUBLE-SIDED DONOR FOR PREPARING A PAIR OF THIN LAMINAE

(75) Inventor: Zuniga Steve, Soquel, CA (US)

Correspondence Address: THE MUELLER LAW OFFICE, P.C., 12951 Harwick Lane, San Diego, CA, 92130, US

(73) Assignee: Twin Creeks Technologies, Inc., San Jose, CA (US)

(21) Appl. No.: 12/347,690

(22) Filed: Dec. 31, 2008

(51) Int. Cl. H01L 21/18

(52) U.S. Cl. 438/68; 257/E21.085

(57) ABSTRACT

A method for forming a photovoltaic cell is disclosed which comprises the steps of providing a semiconductor donor body having a first surface and a second surface opposite the first surface, cleaving a first portion from the first surface of the semiconductor donor body to form a first lamina of semiconductor material, wherein the first lamina of semiconductor material has a first lamina thickness, and cleaving a second portion from the second surface of the semiconductor donor body to form a second lamina of semiconductor material, wherein the second lamina of semiconductor material has a second lamina thickness.

### BACKGROUND OF THE DISCLOSURE

The present disclosure is related to a semiconductor wafer for preparing or manufacturing an assembly such as a photovoltaic cell and more particularly to using a donor body to provide a thin lamina.

Radiation, such as visible light, may be captured and converted to electrical energy through the use of photovoltaic cells. The photovoltaic cell is used to convert the impinging solar energy into electrical power. One type of photovoltaic cell may comprise single crystal semiconductor material, such as silicon. Conventional photovoltaic cells may be formed from crystalline silicon. Typically such wafers are sliced from an ingot of silicon. Silicon wafers can be expensive and can be scarce in supply due to the demands of the semiconductor industry. In view of this, a large portion of the cost of conventional solar cells is due to the cost of silicon feedstock. It would be desirable to manufacture a solar cell that uses a small volume of crystalline silicon. Other aspects such as accommodating various sizes and layouts of photovoltaic assemblies and enabling photovoltaic assemblies to be manufactured in a reliable manner can further improve the performance and commercialization of photovoltaic assemblies or solar cells.

### SUMMARY OF THE DISCLOSURE

In one form of the present disclosure, a method for forming an assembly such as a photovoltaic cell is disclosed. The method comprises the steps of providing a semiconductor donor body having a first surface and a second surface opposite the first surface, cleaving a first portion from the first surface of the semiconductor donor body to form a first lamina of semiconductor material, wherein the first lamina of semiconductor material has a first lamina thickness, and cleaving a second portion from the second surface of the semiconductor donor body to form a second lamina of semiconductor material, wherein the second lamina of semiconductor material has a second lamina thickness.

In another form of the present disclosure a method for forming a photovoltaic cell is disclosed. The method comprises the steps of providing a semiconductor donor body having a first surface and a second surface opposite the first, affixing the first surface of a semiconductor donor body to a receiving surface of a first receiver element, affixing the second surface of the semiconductor donor body to a receiving surface of a second receiver element, cleaving a first semiconductor lamina from the semiconductor donor body at a first cleave plane with the first semiconductor lamina remaining affixed to the first receiver element, and cleaving a second semiconductor lamina from the semiconductor donor body at a second cleave plane with the second semiconductor lamina remaining affixed to the second receiver element.

In yet another form of the present disclosure a method for forming a photovoltaic assembly is disclosed. The method comprises the steps of providing a semiconductor donor body having a first surface and a second surface opposite the first, implanting one or more species of gas ions through the first surface of a semiconductor donor body to define a first cleave plane, implanting one or more species of gas ions through the second surface of the semiconductor donor body to define a second cleave plane, affixing the first surface of the semiconductor donor body to a first receiver element, affixing the second surface of the semiconductor donor body to a second receiver element, cleaving a first lamina from the semiconductor body at the first cleave plane with the first surface remaining affixed to the first receiver element, and cleaving a second lamina from the semiconductor body at the second cleave plane with the second surface remaining affixed to the second receiver element.

Accordingly, a method for simultaneously manufacturing a pair of photovoltaic assemblies with each of the assemblies having a thin lamina bonded to a receiver element is provided. As can be appreciated, savings in both time and costs can be realized when simultaneously or nearly simultaneously manufacturing a pair of photovoltaic assemblies. Cost savings can be realized by processing both sides of the wafer at the same time. For example, any thermal or chemical processing of both sides of the wafer can occur simultaneously. When the wafer is reused after exfoliation, both sides of the wafer can be processed or reconditioned simultaneously. This also increases the throughput of the manufacturing process. Another advantage is that warping or bending stresses are eliminated by processing both sides of the wafer. In particular, when a wafer is bonded to a pair of receiver elements the symmetry of the structure reduces stresses prior to exfoliation of laminae from the wafer.

These and other advantages of the present disclosure will become apparent after considering the following detailed specification in conjunction with the accompanying drawings.

### BRIEF DESCRIPTION OF THE DRAWINGS

FIG. 1 is a side view of a double-sided donor for producing a pair of thin laminae constructed according to the present disclosure;

FIG. 2 is a side view of the double-sided donor shown in FIG. 1 with the pair of thin laminae being exfoliated from the donor;

FIG. 3 is a side view of a double-sided donor being bonded to a pair of receiver elements;

FIG. 4 is a side view of the double-sided donor shown in FIG. 3 with the pair of thin laminae being bonded to the receiver elements and exfoliated from the donor; and

FIG. 5 is a flowchart diagram of a method for manufacturing a pair of thin laminae being bonded to receiver elements.

### DETAILED DESCRIPTION OF THE EMBODIMENTS

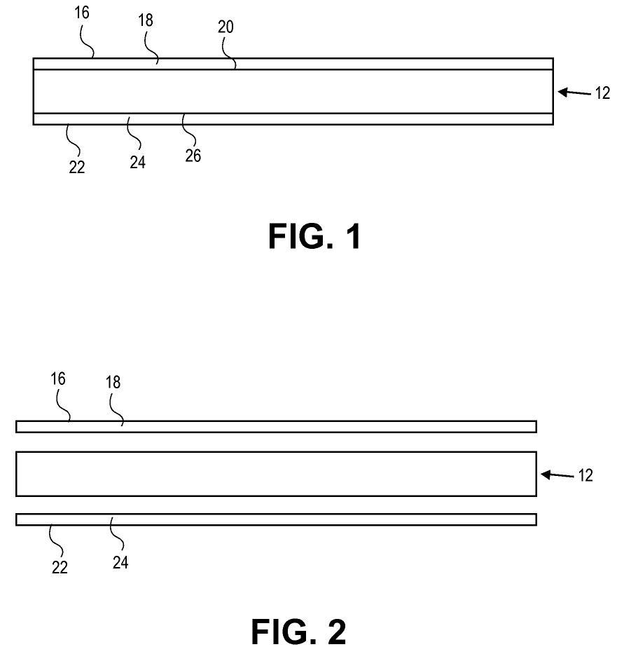

Referring now to the drawings, wherein like numbers refer to like items, FIG. 1 shows an embodiment of a double-sided donor body for producing a pair of thin laminae constructed according to the present disclosure. The donor body is a semiconductor wafer such as a silicon wafer 12 having a top or a first surface 16 having a first lamina portion 18 and a first cleave plane 20. The wafer 12 also comprises a bottom or a second surface 22 having a second lamina portion 24 and a second cleave plane 26. As will be explained in detail further herein, the first lamina portion 18 and the second lamina portion 24 may be exfoliated or cleaved from the wafer 12 at the first cleave plane 20 and the second cleave plane 26, respectively. The second surface 22 is on the opposite side of the silicon wafer 12 than the first surface 16.

In order to be able to exfoliate the lamina portions 18 and 24 the wafer 12 needs to be pretreated in order to create cleave planes 20 and 26. An effective way to be able to cleave the lamina portions 18 and 24 from the wafer 12 is by implanting one or more species of gas ions into the wafer 12 to define the first cleave plane 20 and the second cleave plane 26. The lamina portions 18 and 24 may be exfoliated along the cleave planes 20 and 26, respectively. One or more species of ions is implanted (not shown) through the first surface 16 and the second surface 22 of the wafer 12. A variety of gas ions may be used, including hydrogen and helium, singly or in combination. Each implanted ion will travel some depth beyond first surface 16 and the second surface 22.

After implant, there will be a distribution both of ion depths and of lattice damage; there will be a maximum concentration in each distribution. The ion implantation step defines the cleave planes 20 and 26, and implant energy defines the depth of the cleave planes 20 and 26.

The depth of the implanted ions is determined by the energy at which the gas ions are implanted. At higher implant energies, ions travel farther, increasing the depths of the cleave planes 20 and 26. The depths of the cleave planes 20 and 26 in turn determines the thickness of the first lamina portion 18 and the second lamina portion 24, respectively.

Once ion implantation has been completed, further processing may be performed on the wafer 12. Elevated temperature will induce exfoliation at the cleave planes 20 and 26; thus until exfoliation is intended to take place, care should be taken, for example by limiting temperature and duration of thermal steps, to avoid inducing exfoliation prematurely. Exfoliation may be accomplished by heating the wafer 12 to the exfoliation temperature.

Referring now to FIG. 2, the exfoliation process releases the first lamina 18 and the second lamina 24 from wafer 12. The lamina portions 18 and 24 are typically 1-5 μm thick, however other thickness such as about 0.5 micron to about 20 microns are possible and contemplated, and possibly up to 50 or 100 microns in thickness. Once the lamina portions 18 and 24 are exfoliated from the wafer 12, it may be used again for further processing such as being pretreated again to provide another pair of lamina portions 18 and 24. It is possible and contemplated that the wafer 12 can be used multiple times. After one or more exfoliations, the wafer 12 may be used in a different form for a different manufacturer such as a semiconductor wafer to have an integrated circuit formed therein. Once the lamina portions 18 and 24 have been cleaved from the wafer 12 at the first cleave plane 20 and the second cleave plane 26, the wafer 12 is reduced in thickness.

Further details of how to implant ions into a monocrystalline silicon wafer may be found in co-assigned applications Sivaram et al., U.S. patent application Ser. No. 12/026,530, entitled “Method to Form a Photovoltaic Cell Comprising a Thin Lamina”, filed on Feb. 5, 2008; Herner, U.S. patent application Ser. No. 12/057,265, entitled “Method to Form a Photovoltaic Cell Comprising a Thin Lamina Bonded to a Discrete Receiver Unit”, filed on Mar. 27, 2008; Herner et al., U.S. patent application Ser. No. 12/057,274, entitled “A Photovoltaic Assembly Including a Conductive Layer Between a Semiconductor Lamina and a Receiver Element”, filed on Mar. 27, 2008; Parrill et al., U.S. patent application Ser. No. 12/122,108, entitled “Ion Implanter for Photovoltaic Cell Fabrication”, filed on May 16, 2008; and Benveniste et al., U.S. patent application Ser. No. 12/237,963, entitled “Hydrogen Ion Implanter Using a Broad Beam Source”, filed on Sep. 25, 2008, which are all incorporated herein by this reference.

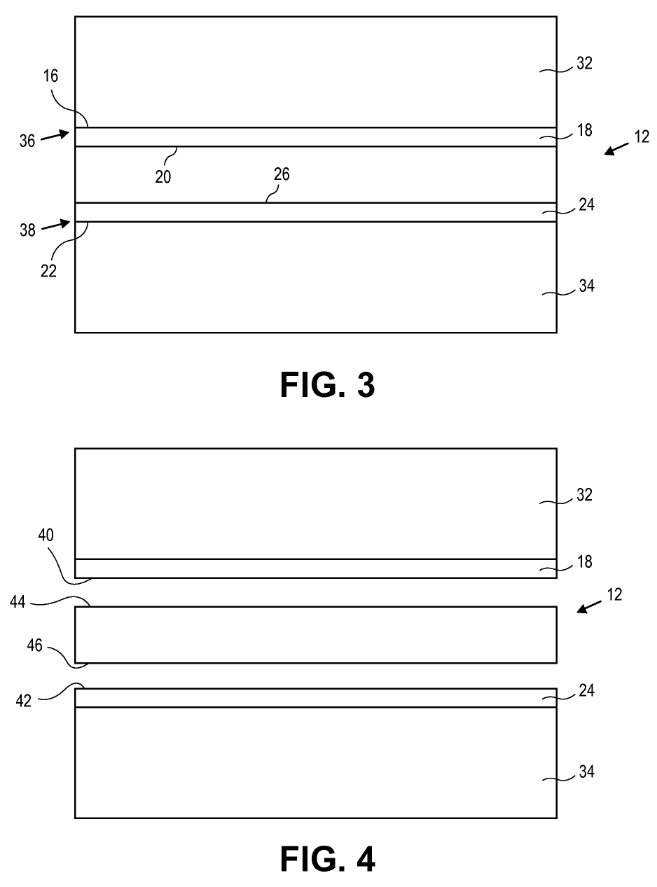

With particular reference now to FIG. 3, once processing to the first surface 16 and the second surface 22 have been completed, the wafer 12 can be bonded or affixed to and between a first receiver element 32 and a second receiver element 34. Note that additional processing may have been performed before affixing to receiver elements 32 and 34. Prior to implanting, the first surface 16 of the wafer 12 and the second surface 22 may be heavily doped, for example by diffusion doping. It is also possible to clean the surfaces 16 and 22 prior to implanting. Other processing steps may include, for example, a surface texturing step, a fabrication of wiring step, a deposition of a transparent conductive oxide step, a deposition of a reflective or conductive material such as a metal, or a deposition of an amorphous silicon layer step may be performed on the wafer 12. The receiver elements 32 and 34 may each also undergo a pretreatment process such as depositing an interfacial layer.

The first surface 16 is bonded to the first receiver element 32 at a first bond interface 36 and the second surface 22 is bonded to the second receiver element 34 at a second bond interface 38. As can be appreciated, bonding both surfaces 16 and 22 simultaneously or nearly simultaneously can result in cost and time savings. Further, prior to bonding the surfaces 16 and 22 and the surfaces of receivers 32 and 34 are cleaned by use of a megasonic rinse/spin dry process to remove any surface particles. The receiver elements 32 and 34 may be comprised of any appropriate material, including glass, ceramic, metal, metal compound, or metallurgical silicon such as low-grade metallurgical silicon. The receiver elements 32 and 34, by way of example only, may be borosilicate or soda lime glass. Anodic bonding may take place by heating the wafer 12 and receiver elements 32 and 34 to a temperature that facilitates bonding and by applying a bias voltage between 200V and 2000V. Bonding temperatures are typically 300° C. to 500° C., for example 350° C. to 450° C., but are not limited to this range. Other bonding methods such as fusion, thermocompression, or a combination thereof are comprehended and possible.

Once the wafer 12 has been bonded to the receiver elements 32 and 34, the lamina portions 18 and 24 are exfoliated or cleaved from the wafer 12. Exfoliation is accomplished by heating the wafer 12 and the receiver elements 32 and 34 to an exfoliation temperature for a specified time. The exfoliation process leaves a thin lamina 18 bonded to the first receiver element 32 and a lamina 24 bonded to the second receiver element 34, and leaves donor wafer 12 with reduced thickness. As previously indicated, once the lamina portions 18 and 24 are exfoliated, the wafer 12 may be used again for further processing such as being pretreated again to provide another pair of lamina portions to be bonded to other receiver elements.

FIG. 4 illustrates a view of the lamina portions 18 and 24 after bonding to the receiver elements 32 and 34 and after exfoliating from the wafer 12. Exfoliation or cleaving creates a new surface 40 of the lamina 18 and a new surface 42 of the lamina 24. Cleaving also creates a new first surface 44 and a new second surface 46 in the wafer 12, now reduced in thickness. Additional processing, such as surface texturing, formation of an antireflective layer, doping, formation of wiring, etc., may be performed on the new surfaces 40 and 42 after exfoliation has taken place. Exfoliation is accomplished when the wafer 12 and the receiver elements 32 and 34 are subjected to an elevated temperature, for example between about 200 and about 800 degrees C., for a sufficient duration. In some embodiments, the temperature step to induce exfoliation is performed at between about 350 and about 550 degrees C., with anneal time on the order of hours at 350 degrees C., and on the order of seconds at 550 degrees C. As the temperature is increased, the duration dwell time required to achieve exfoliation is reduced. It will be apparent that relative dimensions, for example the thickness of the receiver elements 32 and 34, the wafer 12, and the lamina portions 18 and 24, cannot practically be shown to scale in the figures.

The wafer 12 may be formed from an appropriate semiconductor material. An appropriate wafer 12 may be a monocrystalline silicon wafer of any practical thickness, for example from about 200 microns to about 1000 microns thick. In alternative embodiments, the wafer 12 may be thicker; maximum thickness is limited by practicalities of wafer handling and processing. Alternatively, polycrystalline silicon may be used, as may microcrystalline silicon, or wafers or ingots of other semiconductors materials, including germanium, silicon germanium, or III-V or II-VI semiconductor compounds such as GaAs, InP, etc.

The process of forming monocrystalline silicon generally results in circular wafers, but the wafer can have other shapes as well. Cylindrical monocrystalline ingots are often machined to an octagonal cross section prior to cutting wafers. Multicrystalline wafers are often square. Square wafers have the advantage that, unlike circular or hexagonal wafers, they can be aligned edge-to-edge on a photovoltaic module with minimal unused gaps between them. The diameter or width of the wafer 12 may be any standard or custom size. Further, the receiver elements 32 and 34 may be any standard or custom size that may or may not be the same size as the wafer 12. For example, the receiver elements 32 and 34 may be larger than or smaller than the wafer 12.

The two implant steps to define lamina portions 18 and 24 can be performed either simultaneously or sequentially. For example, it is contemplated to employ a device that can hold the wafer 12 to implant the first surface 16 and then flip the wafer 12 to clean the second surface 22. Once the second surface 22 is cleaned the second surface 22 of the wafer 12 can be implanted. As previously described, the wafer 12 can undergo one or more preprocessing steps prior to implantation of ions. After both surfaces 16 and 22 have been implanted, the wafer 12 is positioned to bond the surfaces 16 and 22 to the receiver elements 32 and 34, respectively. Once bonded the wafer 12 and the receiver elements 32 and 34 may be positioned or moved into a chamber, such as an exfoliation oven, to be heated to exfoliate the lamina portions 18 and 24 from the wafer 12. Exfoliation of the lamina portions 18 and 24 can occur virtually simultaneously. The wafer 12 can then be reused or reprocessed. Also, the receiver elements 32 and 34 having the lamina portions 18 and 24 bonded thereto can have post-exfoliation processing performed.

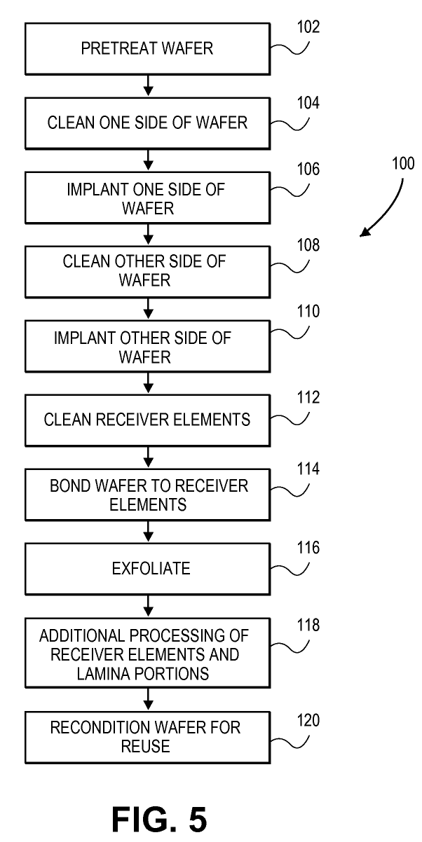

With particular reference now to FIG. 5, a flowchart diagram of a method 100 for manufacturing a pair of thin laminae being bonded to receiver elements is shown. In a first step 102 in which one or more pretreatment steps or processes are applied to the wafer 12. Once the wafer 12 has been pretreated, in a next step 104 one side of the wafer 12 is cleaned. Once this side of the wafer 12 has been cleaned, this side is then implanted in a step 106. The other side of the wafer 12 is then cleaned, as indicated in a step 108. The other side of the wafer 12 is then implanted in a next step 110. Once both sides of the wafer 12 have been implanted, both sides of the wafer 12 and the surfaces of the receiver elements 32 and 34 are cleaned, as is depicted in a step 112. In a next step 114, the wafer 12 is bonded to the receiver elements 32 and 34. Once bonded, the lamina portions 18 and 24 are exfoliated from the wafer 12, as is shown in a step 116. The receiver elements 32 and 34 having the lamina portions 18 and 24 are then sent for additional processing as is depicted in a last step 118. In a final step 120, what is left of the wafer 12 is then sent for further reuse.

While the specification has been described in detail with respect to specific embodiments, it will be appreciated that those skilled in the art, upon attaining an understanding of the foregoing, may readily conceive of alterations to, variations of, and equivalents to these embodiments. These and other modifications and variations to the present double-sided donor body for use in manufacturing a pair of thin lamina portions may be practiced by those of ordinary skill in the art, without departing from the spirit and scope of the present subject matter, which is more particularly set forth in the appended claims. Furthermore, those of ordinary skill in the art will appreciate that the foregoing description is by way of example only, and is not intended to be limiting. Thus, it is intended that the present subject matter covers such modifications and variations as come within the scope of the appended claims and their equivalents.

What is claimed is:

1. A method for forming a photovoltaic cell, the method comprising the steps of:
providing a semiconductor donor body having a first surface and a second surface opposite the first surface;
cleaving a first portion from the first surface of the semiconductor donor body to form a first lamina of semiconductor material, wherein the first lamina of semiconductor material has a first lamina thickness; and
cleaving a second portion from the second surface of the semiconductor donor body to form a second lamina of semiconductor material, wherein the second lamina of semiconductor material has a second lamina thickness.

2. The method of claim 1, wherein the first lamina thickness is between about 0.5 micron and about 20 microns.

3. The method of claim 1, wherein the second lamina thickness is between about 0.5 micron and about 20 microns.

4. The method of claim 1 further comprising the step of implanting one or more species of gas ions through the first surface of the semiconductor donor body to define a first cleave plane with the implanting step occurring before the cleaving of the first portion.

5. The method of claim 4 further comprising the step of heavily doping the first surface of the semiconductor donor body prior to the implanting step.

6. The method of claim 1 further comprising the step of implanting one or more species of gas ions through the second surface of the semiconductor donor body to define a second cleave plane with the implanting step occurring before the cleaving of the second portion.

7. The method of claim 6 further comprising the step of heavily doping the second surface of the semiconductor donor body prior to the implanting step.

8. The method claim 1, wherein the semiconductor donor body is a substantially crystalline silicon wafer.

9. The method of claim 1, wherein the cleaving steps occur simultaneously.

10. A method for forming a photovoltaic cell, the method comprising the steps of:
providing a semiconductor donor body having a first surface and a second surface opposite the first;
affixing the first surface of a semiconductor donor body to a receiving surface of a first receiver element;
affixing the second surface of the semiconductor donor body to a receiving surface of a second receiver element;
cleaving a first semiconductor lamina from the semiconductor donor body at a first cleave plane with the first semiconductor lamina remaining affixed to the first receiver element; and
cleaving a second semiconductor lamina from the semiconductor donor body at a second cleave plane with the second semiconductor lamina remaining affixed to the second receiver element.

11. The method of claim 10, wherein the first receiver element comprises glass, metal, metal compound, metallurgical silicon, ceramic, or plastic.

12. The method of claim 10, wherein the first semiconductor lamina has a thickness between about 0.5 micron and about 20 microns.

13. The method of claim 10, wherein the second semiconductor lamina has a thickness between about 0.5 micron and about 20 microns.

14. The method of claim 10, wherein the semiconductor donor body is a substantially crystalline silicon wafer.

15. The method of claim 10, wherein the cleaving steps occur simultaneously.

16. A method for forming a photovoltaic assembly comprising the steps of:
providing a semiconductor donor body having a first surface and a second surface opposite the first;
implanting one or more species of gas ions through the first surface of a semiconductor donor body to define a first cleave plane;
implanting one or more species of gas ions through the second surface of the semiconductor donor body to define a second cleave plane;
affixing the first surface of the semiconductor donor body to a first receiver element;
affixing the second surface of the semiconductor donor body to a second receiver element;
cleaving a first lamina from the semiconductor body at the first cleave plane with the first surface remaining affixed to the first receiver element; and
cleaving a second lamina from the semiconductor body at the second cleave plane with the second surface remaining affixed to the second receiver element.

17. The method of claim 16, wherein the first receiver element comprises glass, metal, metal compound, metallurgical silicon, ceramic, or plastic.

18. The method of claim 16, wherein the first surface and the first cleave plane define a thickness and the thickness is between about 0.5 micron and about 20 microns.

19. The method of claim 16, wherein the second surface and the second cleave plane define a thickness and the thickness is between about 0.5 micron and about 20 microns.

20. The method of claim 16, wherein the semiconductor donor body is substantially a crystalline silicon wafer.
